(19) United States
(12) Patent Application Publication
(10) Pub. No.: US 2009/0236133 A1
(43) Pub. Date: Sep. 24, 2009

(54) Method of Manufacturing a Polymer and Poymer Material

(75) Inventors: Tadahiro Ohmi, Miyagi (JP); Naoki Tanahashi, Miyagi (JP)

Correspondence Address: FOLEY AND LARDNER LLP;SUITE 500, 3000 K STREET NW, WASHINGTON, DC, 20007, US

(73) Assignee: Tadahiro Ohmi, Sendai-shi, Miyagi (JP)

(21) Appl. No.: 11/991,801

(22) PCT Filed: Sep. 12, 2005
(86) PCT No.: PCT/JP2005/016726

§ 371 Date: Apr. 25, 2008

(51) Int. Cl. H05K 1/00; C08J 3/28

(52) U.S. Cl. 174/258; 522/1

(57) ABSTRACT

In order to provide a method of manufacturing a polymer containing an extremely small amount of residual unreacted monomer component, and a material using the polymer, megasonic is directly radiated to a polymer containing a residual unreacted monomer under an atmosphere free of oxygen and moisture to thereby perfectly complete polymerization.

### TECHNICAL FIELD

The present invention relates to a method of manufacturing a polymer containing an extremely small amount of residual unreacted monomer component and to a material and a member using the polymer.

### BACKGROUND ART

A member using a polymer, such as plastic and rubber, is lightweight and inexpensive and also easy to handle. Therefore, such members are used in large quantity in daily life and in all industries.

However, in recent years, a gas volatilized from the polymer becomes a problem. It is said that a gas volatilized from a building material, an automobile, and so on in daily life is a cause of an allergic disease, such as an atopic dermatitis called a modern disease.

Further, also in a manufacturing process of a semiconductor device, a flat panel display device, or the like, presence of a component volatilized from a polymer used therein has a great influence on device performance to cause decrease in productivity and in reliability.

For a gas volatilized from such a polymer, there exist various kinds of sources, such as an additive agent and a residual solvent. Among them, a residual low-molecular-weight component, in particular, a residual unreacted monomer component left in the polymer is a main component of the volatilized gas and a main factor for exerting an adverse effect. In order to remove the residual unreacted monomer component, it is conceivable that the monomer component is removed by any method after a polymerization reaction or that the polymerization reaction is perfectly completed in the reaction to eliminate the monomer component.

Various methods for removing the residual unreacted monomer component after the polymerization reaction have been reported.

First, high-temperature baking and decompression processing which have been conducted since a long time ago are effective to some extent. However, by these methods, the monomer component can not completely be removed. Further, these methods are not economical because a huge device must be prepared for a large member.

Further, for example, Patent Document 1 and Patent Document 2 describe a method of removing volatile substances in a polymer by bringing, in a hot water tank, the polymer into contact with microscopic bubbles of an inert gas generated by a disperser or ultrasonic irradiation and a method of removing volatile substances contained in a molded polymer by radiating (applying) ultrasonic to the polymer while the polymer is kept into direct contact with a cleaning liquid.

By using the above-mentioned methods, it is possible to reduce the volatile substances. However, it is impossible to completely remove the monomer component which often requires a lot of energy to volatilize.

Patent Document 1: Japanese Unexamined Patent Application Publication (JP-A) No. H07-258331

Patent Document 2: Japanese Unexamined Patent Application Publication (JP-A) No. H07-216115

### DISCLOSURE OF THE INVENTION

### Problem to be Solved by the Invention

The present invention has been made, focusing on the above-mentioned circumstances. It is a technical object of the present invention to provide a method of manufacturing a polymer containing an extremely small amount of residual unreacted monomer component which has been difficult to remove, and a material and a member using the polymer.

### Means to Solve the Problem

A gist of the method of manufacturing a polymer according to the present invention which achieves the above-mentioned object is that the amount of residual unreacted monomer in the polymer is extremely minimized.

That is, according to the present invention, there is provided a method of manufacturing a polymer, which includes the step of causing a polymerization reaction of a monomer by applying energy to the monomer. In the method, during the reaction or after the reaction, megasonic is directly applied to the monomer or a polymer during the reaction or to a polymer produced by the reaction. It is preferable to remove a gas component in the monomer.

According to the present invention, there is provided a method of manufacturing a polymer, in which the megasonic is directly applied to a polymer obtained by a mass polymerization method.

According to the present invention, there is provided a method of manufacturing a polymer, which includes the steps of molding a polymer dissolved in a solvent and heating the molded polymer to remove the solvent. In the method, during removal of at least a part of the solvent or after removal of the solvent, megasonic is directly applied to the polymer.

According to the present invention, in any one of the methods mentioned above, polymerization reaction for obtaining the polymer is carried out under a reduced pressure or under an inert gas atmosphere in which each of the moisture concentration and the oxygen concentration is 1 ppm or less. Alternatively, the megasonic is applied under a reduced pressure or under an inert gas atmosphere in which each of the moisture concentration and the oxygen concentration is 1 ppm or less.

According to the present invention, in any one of the methods mentioned above, the megasonic used therein has a frequency in a range between 0.1 MHz and 100 MHz.

According to the present invention, there is provided a semiconductor sealing material which substantially comprises a polymer manufactured by using any one of the methods mentioned above.

According to the present invention, there is provided a printed wiring board in which a polymer manufactured by using any one of the methods mentioned above is used in at least a part of at least one of a substrate and an interlayer insulation film.

According to the present invention, there is provided an electronic device, such as a semiconductor device, a flat-panel display device, a computer, a cellular phone terminal, and the like, in which a polymer manufactured by using any one of the methods mentioned above is used in at least a part of an interlayer insulation film to form a wiring layer.

According to the present invention, there is provided a transparent photosensitive material which substantially comprises a polymer manufactured by using any one of the methods mentioned above.

According to the present invention, there is provided an optical fiber which substantially comprises a polymer manufactured by using any one of the methods mentioned above.

According to the present invention, there is provided an optical device, in which a polymer manufactured by using any one of the methods mentioned above is used in at least a part of an optical waveguide.

According to the present invention, there is provided a polymer material for coating an electric cable or a distributing cable, which substantially comprises a polymer manufactured by using any one of the methods mentioned above.

According to the present invention, there is provided a building polymer material which substantially comprises a polymer manufactured by using any one of the methods mentioned above.

According to the present invention, there is provided a medical polymer material which substantially comprises a polymer manufactured by using any one of the methods mentioned above.

According to the present invention, there is provided a polymer material for a food product, which substantially comprises a polymer manufactured by using any one of the methods mentioned above.

According to the present invention, there is provided a polymer member for automobiles, ships, aircraft, rockets, or space flight vehicles, which substantially comprises a polymer manufactured by using any one of the methods mentioned above.

### EFFECT OF THE INVENTION

According to the present invention, megasonic is directly radiated (applied) to a polymer containing a residual unreacted monomer so that a polymer containing an extremely small amount of residual unreacted monomer component can be manufactured. If the irradiation is carried out in an atmosphere free of oxygen and moisture, a more remarkable effect is achieved.

### BEST MODE FOR EMBODYING THE INVENTION

The present invention will be described more in detail.

In the present invention, megasonic is directly radiated to a polymer when the polymer is polymerized or to a polymer polymerized to some extent. In this manner, a residual unreacted monomer having a low molecular weight is activated. The residual unreacted monomer activated by the megasonic is increased in collision frequency to become more reactive.

Even in case where the residual unreacted monomer is localized, the megasonic activates the monomer with directivity and it is therefore possible to progress a reaction without deteriorating the polymer.

Further, when the amount of unreacted monomer is large, namely, the polymer is in a liquid state, an effect of the megasonic is attenuated by a gas component dissolved into a system. Hence, degassing is preferably conducted before the reaction.

In case where a reactive atmosphere, such as moisture and oxygen, is present in an atmosphere in which the reaction is induced, a side reaction, such as decomposition of the polymer, is developed or the monomer is reacted to be inactivated. Hence, the reaction in an inert gas atmosphere is preferable.

The present inventors found out that the residual unreacted monomer to be a volatile component is activated by the megasonic and that the monomer is reacted even in a state where it is localized in a solid. Thus, they have reached the present invention.

In the present invention, the megasonic is directly radiated to a reacting system. The frequency of the megasonic is preferably 0.1 to 100 MHz, more preferably 0.5 to 10 MHz, further preferably 0.8 to 5 MHz.

Further, as a method of radiating the megasonic, for example, it is preferable to arrange a megasonic oscillating device immediately below the polymer in a container.

Preferably, the reacting system is as close as possible to the megasonic oscillating device and the polymer has a flat plate shape.

It is not preferable that the polymer is a foamed material or hollow because an effect of the megasonic is reduced.

If degassing of the monomer is carried out when a polymerization reaction of the monomer is caused, the effect of the megasonic is increased.

As a degassing method, a method of reducing the pressure in the entire reacting system is preferable. In this event, by heating to some extent, degassing is easier because the reacting system is decreased in viscosity.

In case where a polymer dissolved in a solvent is molded by coating or the like, it is preferable that the solvent is removed to some extent by heating and thereafter the megasonic is directly radiated to the polymer.

In case where moisture or oxygen is present in the reacting system, the effect of the megasonic is reduced. Therefore, a reaction atmosphere is preferably under vacuum or under an inert gas.

Each of the moisture concentration and the oxygen concentration in the reaction atmosphere is preferably 1 ppm or less, more preferably 100 ppb or less, further preferably 10 ppb or less.

### EXAMPLES

Hereinbelow, examples of the present invention will be described. However, the present invention is not limited to these examples.

### Example 1

Bisphenol A type epoxy resin and hexamethylene diamine as a curing agent were well mixed and applied onto a quartz plate to a thickness of 1 micrometer. Then, the quartz plate was mounted on a megasonic oscillator and put into an airtight container. After the interior of a system was decompressed and degassed, an inert gas was introduced therein and a decompression batch purge was conducted so that each of the moisture concentration and the oxygen concentration in the interior of the system is 1 ppm or less. Thereafter, while megasonic having a frequency of 1 MHz was radiated, heating and baking were carried out at 100° C. for 5 hours.

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 1 ppb or less with respect to the weight of the polymer.

### Example 2

Bisphenol A type epoxy resin and hexamethylene diamine as a curing agent were well mixed and applied onto a quartz plate to a thickness of 1 micrometer. Then, the quartz plate was mounted on a megasonic oscillator and put into an airtight container. After the interior of a system was decompressed and degassed, an inert gas was introduced therein and a decompression batch purge was conducted so that each of the moisture concentration and the oxygen concentration in the interior of the system is 1 ppm or less. Then, heating and baking were carried out at 100° C. for 5 hours and, thereafter, megasonic having a frequency of 1 MHz was radiated at 100° C. for 30 minutes.

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 1 ppb or less with respect to the weight of the polymer.

### Example 3

A polycarbonate plate having a thickness of 1 mm and containing a residual monomer volatile component of 1% or more with respect to the weight of a polymer was mounted on a megasonic oscillator having a frequency of 1 MHz and put into an airtight container. After the interior of a system was decompressed and degassed, an inert gas was introduced therein and a decompression batch purge was conducted so that each of the moisture concentration and the oxygen concentration in the interior of the system is 1 ppm or less. Thereafter, irradiation was carried out at 100° C. for 30 minutes.

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 10 ppm with respect to the weight of the polymer.

### Example 4

Polyimide prepolymer (polyamic acid) dissolved in a solvent was applied onto a quartz plate to a thickness of 1 micrometer. Then, the quartz plate was mounted on a megasonic oscillator and put into an airtight container. After the interior of a system was decompressed and degassed, an inert gas was introduced therein and a decompression batch purge was conducted so that each of the moisture concentration and the oxygen concentration in the interior of the system is 1 ppm or less. Thereafter, while megasonic having a frequency of 1 MHz was radiated, heating and baking were carried out at 300° C. for 5 hours.

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 1 ppb or less with respect to the weight of the polymer.

### Example 5

Polyimide prepolymer (polyamic acid) dissolved in a solvent was applied onto a quartz plate to a thickness of 1 micrometer. Then, the quartz plate was mounted on a megasonic oscillator and put into an airtight container. After the interior of a system was decompressed and degassed, an inert gas was introduced therein and a decompression batch purge was conducted so that each of the moisture concentration and the oxygen concentration in the interior of the system is 1 ppm or less. Then, heating and baking were carried out at 300° C. for 5 hours and, thereafter, megasonic having a frequency of 1 MHz was radiated for 30 minutes.

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 1 ppb or less with respect to the weight of the polymer.

### Comparative Example 1

Bisphenol A type epoxy resin and hexamethylene diamine as a curing agent were well mixed and applied onto a quartz plate to a thickness of 1 micrometer. Then, the quartz plate was put into an airtight container. After the interior of a system was decompressed and degassed, an inert gas was introduced therein and a decompression batch purge was conducted so that each of the moisture concentration and the oxygen concentration in the interior of the system is 1 ppm or less. Thereafter, heating and baking were carried out at 100° C. for 5 hours. (Megasonic was not radiated.)

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 1% or more with respect to the weight of the polymer.

### Comparative Example 2

Bisphenol A type epoxy resin and hexamethylene diamine as a curing agent were well mixed and applied onto a quartz plate to a thickness of 1 micrometer. Without conducting degassing and so on, heating and baking were carried out at 100° C. for 5 hours in a normal atmosphere having a humidity of 50% or more. (Megasonic was not radiated.)

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 1% or more with respect to the weight of the polymer.

### Comparative Example 3

A polycarbonate plate having a thickness of 1 mm and containing a residual monomer volatile component of 1% or more with respect to the weight of a polymer was mounted on a megasonic oscillator having a frequency of 1 MHz and put into an airtight container. After the interior of a system was decompressed and degassed, an inert gas was introduced therein and a decompression batch purge was conducted so that each of the moisture concentration and the oxygen concentration in the interior of the system is 1 ppm or less. Thereafter, without radiating megasonic, only heating was carried out at 100° C. for 30 minutes.

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 1% or more with respect to the weight of the polymer.

### Comparative Example 4

A polycarbonate plate having a thickness of 1 mm and containing a residual monomer volatile component of 1% or more with respect to the weight of a polymer was put into hot water of 80° C. and irradiation was continuously carried out for 1 hour by an ultrasonic oscillator having a frequency of 20 MHz.

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 1% or more with respect to the weight of the polymer.

### Comparative Example 5

Polyimide prepolymer (polyamic acid) dissolved in a solvent was applied onto a quartz plate to a thickness of 1 micrometer. Then, the quartz plate was mounted on a megasonic oscillator and put into an airtight container. After the interior of a system was decompressed and degassed, an inert gas was introduced therein and a decompression batch purge was conducted so that each of the moisture concentration and the oxygen concentration in the interior of the system is 1 ppm or less. Thereafter, without carrying out megasonic irradiation, heating and baking were carried out at 300° C. for 5 hours.

A monomer component volatilized from the polymer after the processing was volatilized at 100° C. under a high-purity argon stream in which each of the moisture concentration and the oxygen concentration is 1 ppb or less. As a result of observation by an atmospheric pressure ionization plasma mass spectrometer, the ratio of the monomer component was 1% or more with respect to the weight of the polymer.

As described in the foregoing, a polymer obtained by the method of manufacturing a polymer according to the embodiment of the present invention does not contain a monomer component. Therefore, the polymer can be used in materials using a polymer in every field, such as a semiconductor sealing material, a printed board, an interlayer insulation film, and a transparent photosensitive material in semiconductor manufacturing, electronic, electric, and communications materials including an optical fiber, an optical waveguide, or the like used in optical communication, electronic, electric, and communications materials including a coating material for an electric cable, an electric wire, and a distributing cable, a building material, a medical material, a material for a food product, and a member for automobiles, ships, aircraft, and rockets.

### INDUSTRIAL APPLICABILITY

The method of manufacturing a polymer according to the present invention is applicable, because the polymer does not contain a monomer component, to a polymer material in various fields, such as a semiconductor sealing material, a printed board, an interlayer insulation film, a transparent photosensitive material, an optical fiber, an optical waveguide, a coating material for an electric cable and a distributing cable, a building material, a medical material, a material for a food product, and a member used in automobiles, ships, aircraft, and rockets.

1. A method of manufacturing a polymer, including the step of causing a polymerization reaction of a monomer by applying energy to the monomer, wherein, during the reaction or after the reaction, megasonic is directly applied to the monomer or a polymer during the reaction or to a polymer produced by the reaction.

2. The method of manufacturing a polymer as claimed in claim 1, the method further including the step of removing a gas component in the monomer before the step of causing the polymerization reaction.

3. The method of manufacturing a polymer as claimed in claim 1, wherein the polymerization reaction for obtaining the polymer is carried out under a reduced pressure or under an inert gas atmosphere in which each of the moisture concentration and the oxygen concentration is 1 ppm or less.

4. The method of manufacturing a polymer as claimed in claim 1, wherein the megasonic is applied under a reduced pressure or under an inert gas atmosphere in which each of the moisture concentration and the oxygen concentration is 1 ppm or less.

5. The method of manufacturing a polymer as claimed in claim 1, wherein the megasonic has a frequency in a range between 0.1 MHz and 100 MHz.

6. A printed wiring board, wherein a polymer manufactured by using the method of manufacturing a polymer claimed in claim 1 is used in at least a part of at least one of a substrate and an interlayer insulation film.

7. An electronic device, wherein a polymer manufactured by using the method of manufacturing a polymer claimed in claim 1 is used in at least a part of an interlayer insulation film to form a wiring layer.

8. A transparent photosensitive polymer material substantially comprising a polymer manufactured by using the method of manufacturing a polymer claimed in claim 1.

9. An optical fiber substantially comprising a polymer manufactured by using the method of manufacturing a polymer claimed in claim 1.

10. An optical device, wherein a polymer manufactured by using the method of manufacturing a polymer claimed in claim 1 is used in at least a part of an optical waveguide.

11. A building polymer material substantially comprising a polymer manufactured by using the method of manufacturing a polymer claimed in claim 1.

12. A medical polymer material substantially comprising a polymer manufactured by using the method of manufacturing a polymer claimed in claim 1.

13. A polymer material for a food product, substantially comprising a polymer manufactured by using the method of manufacturing a polymer claimed in claim 1.

14. A polymer member for automobiles, ships, aircraft, rockets, or space flight vehicles, substantially comprising a polymer manufactured by using the method of manufacturing a polymer claimed in claim 1.

15. A semiconductor sealing material substantially comprising a polymer manufactured by using the method of manufacturing a polymer claimed in claim 1.

16. A polymer material for coating an electric cable or a distributing cable, substantially comprising a polymer manufactured by using the method of manufacturing a polymer claimed in claim 1.

17. A method of manufacturing a polymer, wherein megasonic is directly applied to a polymer obtained by a mass polymerization method.

18. The method of manufacturing a polymer as claimed in claim 17, wherein a polymerization reaction for obtaining the polymer is carried out under a reduced pressure or under an inert gas atmosphere in which each of the moisture concentration and the oxygen concentration is 1 ppm or less.

19. The method of manufacturing a polymer as claimed in claim 17, wherein the megasonic is applied under a reduced pressure or under an inert gas atmosphere in which each of the moisture concentration and the oxygen concentration is 1 ppm or less.

20. The method of manufacturing a polymer as claimed in claim 17, wherein the megasonic has a frequency in a range between 0.1 MHz and 100 MHz.

21. A printed wiring board, wherein a polymer manufactured by using the method of manufacturing a polymer claimed in claim 17 is used in at least a part of at least one of a substrate and an interlayer insulation film.

22. An electronic device, wherein a polymer manufactured by using the method of manufacturing a polymer claimed in claim 17 is used in at least a part of an interlayer insulation film to form a wiring layer.

23. A transparent photosensitive polymer material substantially comprising a polymer manufactured by using the method of manufacturing a polymer claimed in claim 17.

24. An optical fiber substantially comprising a polymer manufactured by using the method of manufacturing a polymer claimed in claim 17.

25. An optical device, wherein a polymer manufactured by using the method of manufacturing a polymer claimed in claim 17 is used in at least a part of an optical waveguide.

26. A building polymer material substantially comprising a polymer manufactured by using the method of manufacturing a polymer claimed in claim 17.

27. A medical polymer material substantially comprising a polymer manufactured by using the method of manufacturing a polymer claimed in claim 17.

28. A polymer material for a food product, substantially comprising a polymer manufactured by using the method of manufacturing a polymer claimed in claim 17.

29. A polymer member for automobiles, ships, aircraft, rockets, or space flight vehicles, substantially comprising a polymer manufactured by using the method of manufacturing a polymer claimed in claim 17.

30. A semiconductor sealing material substantially comprising a polymer manufactured by using the method of manufacturing a polymer claimed in claim 17.

31. A polymer material for coating an electric cable or a distributing cable, substantially comprising a polymer manufactured by using the method of manufacturing a polymer claimed in claim 17.

32. A method of manufacturing a polymer, including the steps of molding a polymer dissolved in a solvent and heating the molded polymer to remove the solvent, wherein, during removal of at least a part of the solvent or after removal of the solvent, megasonic is directly applied to the polymer.

33. The method of manufacturing a polymer as claimed in claim 32, wherein a polymerization reaction for obtaining the polymer is carried out under a reduced pressure or under an inert gas atmosphere in which each of the moisture concentration and the oxygen concentration is 1 ppm or less.

34. The method of manufacturing a polymer as claimed in claim 32, wherein the megasonic is applied under a reduced pressure or under an inert gas atmosphere in which each of the moisture concentration and the oxygen concentration is 1 ppm or less.

35. The method of manufacturing a polymer as claimed in claim 32, wherein the megasonic has a frequency in a range between 0.1 MHz and 100 MHz.

36. A printed wiring board, wherein a polymer manufactured by using the method of manufacturing a polymer claimed in claim 32 is used in at least a part of at least one of a substrate and an interlayer insulation film.

37. An electronic device, wherein a polymer manufactured by using the method of manufacturing a polymer claimed in claim 32 is used in at least a part of an interlayer insulation film to form a wiring layer.

38. A transparent photosensitive polymer material substantially comprising a polymer manufactured by using the method of manufacturing a polymer claimed in claim 32.

39. An optical fiber substantially comprising a polymer manufactured by using the method of manufacturing a polymer claimed in claim 32.

40. An optical device, wherein a polymer manufactured by using the method of manufacturing a polymer claimed in claim 32 is used in at least a part of an optical waveguide.

41. A building polymer material substantially comprising a polymer manufactured by using the method of manufacturing a polymer claimed in claim 32.

42. A medical polymer material substantially comprising a polymer manufactured by using the method of manufacturing a polymer claimed in claim 32.

43. A polymer material for a food product, substantially comprising a polymer manufactured by using the method of manufacturing a polymer claimed in claim 32.

44. A polymer member for automobiles, ships, aircraft, rockets, or space flight vehicles, substantially comprising a polymer manufactured by using the method of manufacturing a polymer claimed in claim 32.

45. A semiconductor sealing material substantially comprising a polymer manufactured by using the method of manufacturing a polymer claimed in claim 32.

46. A polymer material for coating an electric cable or a distributing cable, substantially comprising a polymer manufactured by using the method of manufacturing a polymer claimed in claim 32.
